(19) United States
(12) Patent Application Publication
(10) Pub. No.: US 2018/0145697 A1
(43) Pub. Date: May 24, 2018

(54) AUDIO DIGITAL-TO-ANALOG CONVERTER WITH ENHANCED DYNAMIC RANGE

(71) Applicant: Synaptics Incorporated, San Jose, CA (US)

(72) Inventors: Lorenzo Crespi, Costa Mesa, CA (US); Claudio De Berti, Irvine, CA (US)

(21) Appl. No.: 15/821,534

(22) Filed: Nov. 22, 2017

Related U.S. Application Data
(60) Provisional application No. 62/425,510, filed on Nov. 22, 2016.

(51) Int. Cl. H03M 1/00; G06F 3/16

(52) U.S. Cl. CPC H03M 1/002; G06F 3/165

(57) ABSTRACT

An audio digital-to-analog converter (DAC) achieves high dynamic range with low power consumption using a segmented DAC, also referred to as a noise shaped splitter. The noise shaped splitter is dynamically reconfigured based on envelope detection that tracks the amplitude of an n-bit digital input signal to the segmented DAC. The amplitude of the n-bit digital input signal can be expressed as the magnitude of a numerical value corresponding to the n bits of the digital signal. Based on the amplitude of the digital input signal, certain segments of the segmented DAC are bypassed and the components of each bypassed segment are turned off, saving power and reducing noise, and achieving improved dynamic range along with lower power consumption.

### CROSS-REFERENCE TO RELATED APPLICATIONS

This application claims the benefit of and priority to U.S. Provisional Patent Application No. 62/425,510 filed Nov. 22, 2016 and entitled “AUDIO DIGITAL-TO-ANALOG CONVERTER WITH ENHANCED DYNAMIC RANGE,” which is incorporated herein by reference in its entirety.

### TECHNICAL FIELD

The present disclosure generally relates to signal processing and, more particularly, to a digital-to-analog converter that provides enhanced dynamic range with low power consumption.

### BACKGROUND

Signal processing systems, and in particular systems incorporating low power audio devices such as smartphones, tablets, and portable playback devices, have driven a need in the art for high-performance audio digital-to-analog converter (DAC) structures that achieve the high dynamic range with low power consumption.

### SUMMARY

An audio digital-to-analog converter (DAC) in accordance with one or more embodiments of the present disclosure provides an improved solution for achieving high dynamic range with low power consumption. In one embodiment, a segmented DAC is dynamically reconfigured based on envelope detection that tracks the amplitude of the digital input signal to the segmented DAC. The amplitude of an n-bit digital input signal can be expressed as the magnitude of a numerical value corresponding to the n bits of the digital signal. Based on the amplitude of the digital input signal, certain segments of the segmented DAC can be bypassed and the data splitter, dynamic element matching (DEM), and weighted DAC of each bypassed segment can be turned off, saving power and reducing noise for improved dynamic range at lower power consumption compared to a DAC that is not dynamically reconfigured.

In one embodiment, a digital-to-analog conversion system includes a data splitter configured to split a digital input signal into multiple data segments such that the digital input signal is expressed as a combination of one or more of the data segments; and a configuration controller that is configured to provide power to elements of the system used for processing those data segments that are required for the combination to express the digital input signal.

In one embodiment, a digital-to-analog conversion system comprises a data splitter operable to split a digital input signal into a plurality of data segments, wherein the digital input signal is expressed as a combination of the plurality of data segments, a plurality of signal paths, each of the plurality of signal paths having a plurality of processing elements operable to receive and process a corresponding one of the plurality of data segment, and a configuration controller operable to determine a subset of the plurality of data segments sufficient to express the digital input signal and selectively provide power to the processing elements of each signal path for selectively processing each data segment in the subset of data segments.

In one embodiment, the subset of data segments comprises data segments required for a combination of the subset of data segments to express the digital input signal, and wherein the configuration controller is operable to feed the required data segments to corresponding processing elements. The system may further comprise an envelope detector operable to determine which of the plurality of data segments are sufficient to form a combination to express the digital input signal. In one embodiment, each of the plurality of data segments has a weight corresponding to a level of amplitude of the digital input signal and the configuration control is operable to provide power to the processing elements corresponding to the data segments of a minimum weight up to and including the data segment having the weight corresponding to a current amplitude of the input signal.

In one embodiment, the system further comprises a dynamic element matching module arranged to receive an output of the data splitter and a control signal from configuration controller, the dynamic element matching module operable to receive one of the data segments and perform data shuffling on the data segment when enabled by the configuration controller. The system may also comprise a digital-to-analog converter controlled by the configuration controller, the digital-to-analog converter operable to receive one of the data segments and produce an analog signal at a gain corresponding to a determined weight of the received one of the data segments.

In one embodiment, the data splitter further comprises a plurality of digital modulators controlled by the configuration controller, the plurality of digital modulators operable to generate data segments having weights corresponding to a level of amplitude of the digital input signal, the each data segment having a weight corresponding to a level of amplitude from a minimum amplitude up to and including a weight corresponding to a current amplitude of the input signal.

In various embodiments, a digital-to-analog conversion system comprises a data splitter operable to split a digital input signal into a plurality of data segments, wherein the digital input signal is expressed as a combination of one or more of the plurality of data segments, a plurality of signal paths, each signal path having a plurality of processing elements operable to receive and process a corresponding one of the plurality of data segments, and a configuration controller operable to selectively supply power to processing elements used for processing the plurality of data segments, wherein the configuration controller disables processing elements not required for a subset of data segments to express the digital input signal.

In one embodiment, the configuration controller is operable to bypass processing elements corresponding to the plurality of data segments not required for the subset to express the digital input signal. The system may further comprise an envelope detector operable to determine which of the plurality of data segments are not required for the subset to express the digital input signal. In one embodiment, each of the plurality of signal paths has an associated weight corresponding to a level of amplitude of the digital input signal and wherein the configuration controller is operable to selectively supply power to the processing elements used for processing the plurality of data segments corresponding to a minimum weight up to and including the data segment having the weight corresponding to a current amplitude of the input signal.

In one embodiment, the system further comprises a dynamic element matching module connected to the data splitter and controlled by the configuration controller, the dynamic element matching module operable to receive a corresponding one of the data segments and perform data shuffling on the data segment when enabled by the configuration control. In one embodiment, each signal path has an associated weight corresponding to a level of amplitude of the digital input signal, the system further comprising a digital-to-analog converter controlled by the configuration controller and operable to receive a corresponding one of the data segments and produce an analog signal at a gain corresponding to a weight of the data segment.

In one embodiment, each data segment has a weight corresponding to a level of amplitude of the digital input signal, the system further comprising a digital-to-analog converter controlled by the configuration controller and operable to receive a corresponding one of the shuffled data segments from the dynamic element matching module and produce an analog signal at a gain corresponding to a weight of the data segment.

In various embodiment, a method of converting a digital input signal to an analog signal, the method comprises splitting the digital input signal into a plurality of data segments, wherein each data segment comprises a portion of the digital input signal such that the digital input signal is expressed by a weighted sum of the data segments, wherein at least one data segment having a minimum weight is required for the weighted sum to express the digital input signal, and controlling a configuration of a signal processor to selectively enable and disable processing elements used for processing the data segments, wherein data segments that are required for the weighted sum to express the digital input signal are enabled, and data segments that are not required for the weighted sum to express the digital input signal are disabled.

In one embodiment, the method further comprises controlling the configuration of the signal processor to feed the data segments required for the weighted sum to express the digital input signal to processing elements used for processing those data segments, and to bypass those processing elements corresponding to data segments that are not required for the weighted sum to express the digital input signal. The method may also comprise determining which of the plurality of data segments are required for the weighted sum to express the digital input signal.

In one embodiment, the method further comprises assigning a weight to each data segment such that each weight corresponds to a range of amplitude values of the digital input signal, and controlling the configuration of the signal processor to selectively provide power to the processing elements corresponding to the data segments of a minimum weight up to and including the data segment having the weight corresponding to a current amplitude of the input signal. The method may further comprise assigning a weight to each data segment such that each weight corresponds to a distinct level of amplitude of the digital input signal, controlling the configuration of the signal processor to enable dynamic element matching on the data segments corresponding to the minimum weight and data segments having weights up to and including the weight of the data segment corresponding to a current amplitude of the input signal, and performing dynamic element matching according to the current configuration.

In one embodiment, the method may further comprise assigning a weight to each data segment such that each weight corresponds to a distinct level of amplitude of the digital input signal, controlling the configuration of the signal processor to selectively enable digital-to-analog converters on the signal path corresponding to the data segments having a minimum weight up to and including the data segments having the weight corresponding to a current amplitude of the input signal, and converting, according to the current configuration, a data segment to an analog signal at a gain corresponding to the weight of the data segment.

### BRIEF DESCRIPTION OF THE DRAWINGS

FIG. 1 is a system block diagram of a system for digital-to-analog conversion of a digital input signal, in accordance with one or more embodiments.

FIGS. 2A-C is a sequence of block diagrams illustrating operation of a system for digital-to-analog conversion in accordance with an embodiment.

FIG. 3A is a data diagram illustrating segmenting of data for an 8-bit digital input signal in accordance with one embodiment. FIG. 3B, is a circuit block diagram for a data splitter segmented according to the example of FIG. 3A, in accordance with one embodiment.

FIG. 4 is a flow chart of a method of digital-to-analog conversion of a digital input signal, according to an embodiment.

The included drawings are for illustrative purposes and serve only to provide examples of possible systems and methods for the disclosed methods and system for providing context aware audio processing. These drawings in no way limit any changes in form and detail that may be made to that which is disclosed by one skilled in the art without departing from the spirit and scope of this disclosure.

### DETAILED DESCRIPTION

A digital-to-analog converter that is dynamically reconfigurable to increase the dynamic range, while maintaining low power consumption for digital signal processing is disclosed along with corresponding systems and methods that are particularly well-suited for audio systems and systems incorporating low power audio devices, such as smartphones, tablets, and portable playback devices.

There is a need in the art for high-performance audio digital-to-analog converter (DAC) structures that achieve a high dynamic range (DR) while using a low level of power consumption. The dynamic range of a DAC may be measured as the ratio of a full scale (FS) output signal to the noise floor when the output is at −60 decibels (dB) from full scale. One way to increase dynamic range is to reduce the noise floor when small amplitude signals (e.g., signals at −60 dB) are reproduced.

In one embodiment, the noise floor is defined as a combination of thermal noise generated by the digital-to-analog converter's analog section and high frequency shaped quantization noise modulated back to the baseband both by nonlinearities and high frequency jitter component present in the clock (e.g., time interval error (TIE) jitter). One approach for reducing jitter sensitivity is to decrease the shaped quantization noise, which can be accomplished, for example, by increasing the number of quantization levels of the DAC. This approach has the drawback, however, of increasing the complexity of the dynamic element matching (DEM) techniques used to linearize the DAC.

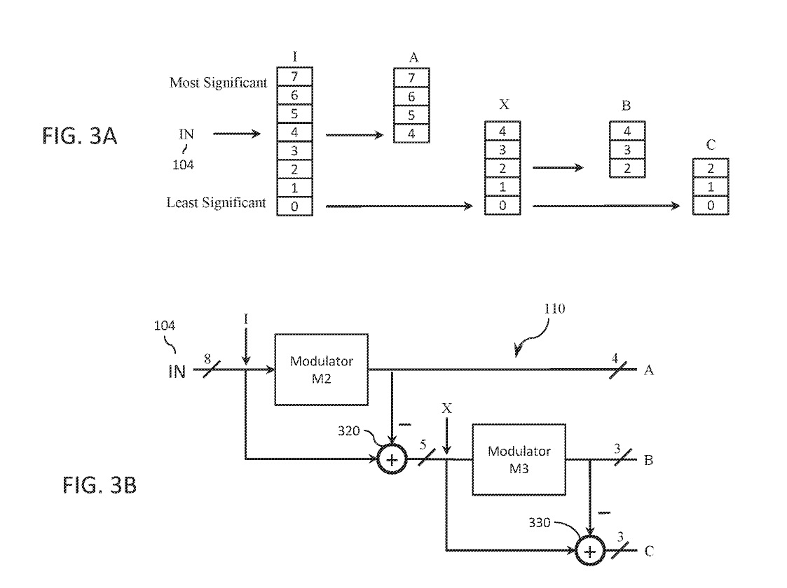

In order to reduce the DEM complexity, a technique known as segmentation (or noise shaped splitting) has been used in which the n-bit digital signal can be segmented into a multiple digital signals, each having less than n bits, so that each smaller segment can be processed and recombined with the other segments. Such segmentation techniques are disclosed in “A 113-dB SNR oversampling DAC with segmented noise-shaped scrambling” by R. Adams and K. Q. Nguyen, in IEEE Journal of Solid-State Circuits, vol. 33, no. 12, pp. 1871-1878, December 1998, and in “A 108 dB SNR, 1.1 mW Oversampling Audio DAC With A Three-level DEM Technique” by K. Nguyen, A. Bandyopadhyay, B. Adams, K. Sweetland and P. Baginski, in IEEE Journal of Solid-State Circuits, vol. 43, no. 12, pp. 2592-2600, December 2008, both of which are incorporated by reference. The example presented in FIGS. 3A and 3B is based on those references.

Some features of these segmentation techniques can limit the dynamic range achievable. One or more embodiments disclose additional techniques and modifications that achieve improved dynamic range over audio systems employing the known segmentation techniques in view of considerations involving thermal noise, gain error between the DACs for the various segments, and power consumption.

For example, in one embodiment, by selective utilization of DACs for small signal operation vs. large signal operation, thermal noise is lowered for small signal operation compared to large signal operation, which increases the dynamic range. Also for example, in one embodiment, selective utilization of DACs for small signal operation vs. large signal operation can avoid or reduce DAC-to-DAC gain error by eliminating some of the DACs that contribute to the error, which also increases the dynamic range. In addition, selective utilization of DACs for small signal operation vs. large signal operation can greatly reduce power consumption when small signals are reproduced, which reduces the overall power consumption for the digital-to-analog conversion system as a whole. In one or more embodiments, the reduced power consumption can produce the further benefit of a class-H dynamic power consumption.

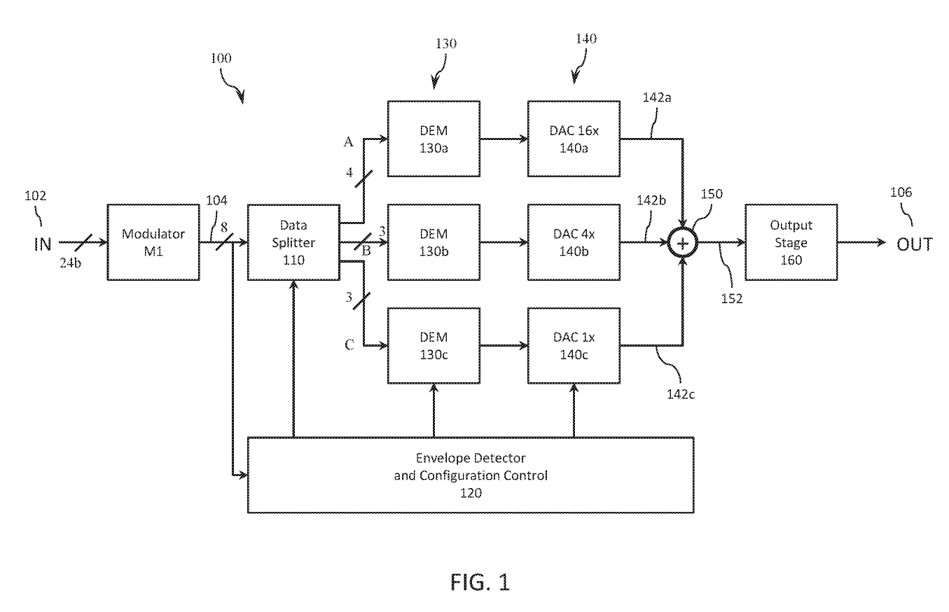

FIG. 1 illustrates a system 100 for digital-to-analog conversion of a digital input signal, in accordance with one or more embodiments. System 100 may be part of any electronic device, such as an audio codec, smartphone, tablet, television, or computer, for example, or systems incorporating low power audio devices, such as smartphones, tablets, and portable playback devices.

Digital-to-analog conversion system 100 may receive digital input signal 102 and pass digital input signal 102 to digital modulator M1. Digital input signal 102, as indicated in FIG. 1, may be a 24-bit signal, for example, that is received from digital signal processing circuits that may include oversampling and interpolation filtering circuits (not shown). Digital modulator M1 may be an 8-bit, second-order, sigma-delta modulator (SDM), for example, that passes input signal 102 as an 8-bit, noise shaped signal 104, having low in-band noise, to data splitter 110 and envelope detector and configuration control 120.

For the embodiment used as an illustrative example in FIGS. 1, 3A and 3B, data splitter 110 segments 8-bit digital input signal 104 into three digital signals A, B, and C such that, mathematically, the combination can be expressed as input signal 104=16A+4B+C. Viewed as data, the data of input signal 104 can be recombined from the data of the multiple data segments A, B, and C. For this example, signal A is a 4-bit signal, signal B is a 3-bit signal, and signal C is also a 3-bit signal, as indicated in FIG. 1. The corresponding data segments may have, respectively, the same number of bits. In this example, segment A has a weight of 16, segment B has a weight of 4, and segment C has a weight of 1.

Data segments, or signals, A, B, and C may be passed to dynamic element matching (DEM) circuits 130, respectively, to DEM 130a, DEM 130b, and DEM 130c, as shown in FIG. 1. Dynamic element matching may operate to randomize mismatched components of the analog elements of the DAC circuits 140. For example, dynamic element matching (e.g., each DEM 130) may be implemented using a scrambler that pseudo-randomly directs different bits of the signal to different circuit elements at different times (e.g., shuffles the signal) to effectively cancel out the effects of component mismatch of the circuit elements on the signal, e.g., signal A, B, or C, processed by each DAC 140. In this example, DEM 130a provides dynamic element matching on signal A for corresponding DAC 140a, and the weight, 16, of data segment A may also be referred to as the weight of corresponding DAC 140a. Similar descriptions apply to DAC 140b and DAC 140c.

Envelope detector and configuration control 120 may be configured to track the amplitude (e.g., the envelope) of signal 104 as it changes and determine from the amplitude at each sample time (e.g., clock cycle) which data segments are needed to express, or to reconstruct, signal 104. For example, envelope detector and configuration control 120 may receive 8-bit digital input signal 104 and, viewing the signal 104 as data, determine which of the data segments A, B, and C are needed to express signal 104 as a weighted combination. So, for example, signal 104 can be expressed as signal 104=16A+4B+C, regardless of amplitude, whether full, intermediate, or zero amplitude. However, the data of segment A may be zero when signal 104 has medium amplitude, and then signal 104 can be expressed as signal 104=4B+C. In that case, only segments B and C are required to express, or to reconstruct, signal 104. When signal 104 has low amplitude, only segment C may be required to express, or to reconstruct, signal 104, for example. Each data segment is given a weight that corresponds to a level of amplitude of the digital input signal. The weight can be, for example, the minimum amplitude of a signal that can be expressed using that data segment and the segments of lesser weight. In this example, A has weight 16, B has weight 4, and C has weight 1.

Envelope detector and configuration control 120, thus, may be configured to determine from the amplitude of signal 104 at each sample time, or clocking of the 8-bit input signal 104, which data segments are needed to express, or to reconstruct, signal 104. Envelope detector and configuration control 120 may then control operation of system 100 according to which data segments, e.g., a subset of A, B, and C, are required to express signal 104. For example, envelope detector and configuration control 120 may control (as indicated in FIG. 1) switching of data splitter 110 (e.g., modulators, adders, and other circuit elements data splitter 110), DEMs 130, and DACs 140 to enable or disable (e.g., supply or cut power to) certain parts of system 100, as well as to redirect all or parts of the signals A, B, and C, to reconfigure system 100 for optimal operation with regard to noise reduction, gain error between the DACs 140, and power consumption, for example, that improve the dynamic range of system 100.

Summer 150 may recombine the weighted signals from each of the DACs 140 to produce an analog signal 152 corresponding to the digital input signal 102. For example, the gain of each DAC 140 may be scaled according to the weight of each DAC (e.g., 16×. 4×, and 1× according to the segment A, B, and C) so that summer 150 can simply combine the signals 142a, 142b, and 142c. The gain error between the DACs (or DAC-to-DAC error) can be described as the amount by which the DAC gains do not exactly match the DAC weights.

In the case of current steering DACs 140 providing current signals 142a, 142b, and 142c, a current to voltage conversion may be provided by output stage 160 to convert signal 152 to an analog output voltage signal 106 that corresponds to digital input signal 102. Output voltage signal 106 may be output to an audio power amplifier, for example, or to a transducer such as headphones or a loudspeaker.

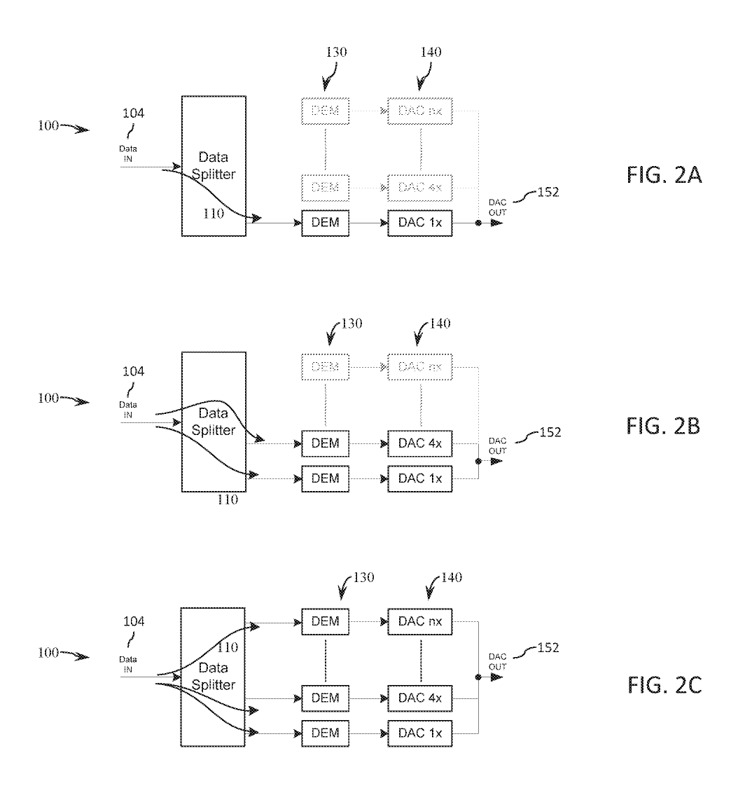

FIGS. 2A, B & C is a sequence of block diagrams illustrating operation of system 100 for digital-to-analog conversion in accordance with an embodiment. FIG. 2 illustrates dynamic reconfiguration of a segmented DAC, which may comprise data splitter 110, DEMs 130, weighted DACs 140 and summer 150, as seen in FIG. 1. An envelope detector (such as envelope detector and configuration control 120 shown in FIG. 1) tracks the amplitude of the digital signal 104 at the input of the segmented DAC.

When signal 104 has a low enough amplitude, it can be expressed within the levels of the DAC with the least weight, requiring only the segment, DEM, and DAC 1× shown as solid lines in FIG. 2A; only that segment, DEM, and DAC 1× are enabled and have signals fed to them and the other segments are bypassed and their DACs are turned off, shown as phantom lines in FIG. 2A. For example, in the embodiment of FIG. 1, if signal 104 has low enough amplitude to be expressible within the 3 bits of segment C, only DEM 130c, DAC 140c, and those portions of data splitter 110 and summer 150 needed to produce output signal 152 may be enabled and fed signals.

When signal 104 has an intermediate amplitude that can be expressed within the levels obtained with the segmentation technique applied to the two DACs with least weights, requiring only the segments, DEMs, DAC 4× and DAC 1× shown as solid lines in FIG. 2B, then only those segments, DEM, DAC 4× and DAC 1× are enabled and have signals fed to them and the other segments are bypassed and their DACs are turned off, shown as phantom lines in FIG. 2B.

As indicated by ellipses in FIG. 2, this process can be generalized to any number of segments depending on the particular segmentation implemented by the data splitter 110.

When the signal 104 has an amplitude that, to be expressed, requires levels obtained with the segmentation technique applied to the DAC with the highest weight, e.g., DAC n×, then all the segments, DEMs, DAC n×, . . . , DAC 4× and DAC 1× shown as solid lines in FIG. 2C are enabled and have signals fed to them, and none of the segments are bypassed. Thus, the number of distinct operational states may be equal to the number of segments. For the embodiment illustrated in FIG. 1, for example, the number of segments is three.

Dynamic reconfiguration of the segmented DAC, as illustrated by FIG. 2, for example, provides a number of improvements over a segmented DAC that does not employ such dynamic reconfiguration, such as improved dynamic range and lower power consumption, both of which can be obtained concurrently.

One improvement concerns thermal noise. Without dynamic reconfiguration, the signal is processed by the DAC with the highest weight, while the DACs with smaller weights process the quantization noise. Because the thermal noise is proportional to the weight of each DAC, the noise floor is dominated by the thermal noise generated by the DAC with the highest weight, even for small amplitude output signals, thus limiting the DR.

With dynamic reconfiguration, at small amplitude signal operation (e.g., when only the DAC with the least weight is used and larger weight, unneeded DACs are disabled) the thermal noise is lowered compared to large signal operation, thus increasing the dynamic range.

A second improvement concerns the gain error between the weighted DACs. Without dynamic reconfiguration, and if the data splitter is implemented as a first order sigma-delta modulator, as in the examples presented here, the DAC-to-DAC gain error is shaped only by a first order high-pass function, thus limiting the dynamic range. In general, the data splitter could be implemented as a higher order modulator which shapes the DAC-to-DAC gain error by a higher order high-pass function. Attempts to reduce the DAC-to-DAC gain error directly can entail advanced integrated circuit chip layout techniques that are required to minimize the mismatch between the DACs, and increase the complexity and the design area on the chip.

With dynamic reconfiguration, at small amplitude signal operation (e.g., when only the DAC with the least weight is used and larger weight, unneeded DACs are disabled) DAC-to-DAC gain error can be avoided, since only one DAC is used. Thus, using dynamic reconfiguration, DAC-to-DAC gain error does not affect the dynamic range.

Also, with dynamic reconfiguration, the linearity of the system 100 can be improved insofar as the tones shaped by the DEM are further suppressed by the gain ratio between the DAC with the highest weight and the one with the least weight, which increases the dynamic range.

Dynamic reconfiguration of the segmented DAC also produces benefits in the mid-amplitude range of signal operation (e.g., when the segmentation is applied only to the DACs with less than the maximum weight). Those considerations that apply for small signal operation are still valid concerning thermal noise because the higher weight DACs are bypassed. Also, considerations that apply concerning linearity are still valid, because the DAC-to-DAC gain error is less critical, since it affects a lower number of DACs with weights closer to each other.

Another improvement is related to power consumption and correlates to the fact that without dynamic reconfiguration, the signal is processed by the DAC with the highest weight (e.g., all the DACs) even if the output signal is small, i.e., the signal is expressed in the least or the lower weight DAC levels. Without dynamic reconfiguration, the signal may be the result of the subtraction of a large signal generated by the DAC with the highest weight and the smaller quantization signals generated by the DACs with less weights. In that case, each of the DACs is always active; in other words, the power consumption for the signal at small amplitude is comparable to the power consumption for the signal at full scale. There is no power saving for small amplitude signals as there is when using dynamic reconfiguration.

With dynamic configuration, a dynamic power consumption resembling operation of a class-H amplifier can be achieved. In general, a class-H amplifier is a type of linear amplifier where the power rail voltages are moved up and down according to the envelope of the signal, decreasing power losses in the amplifier. In one or more embodiments, the power consumption of the DAC moves up and down with the envelope of the signal, analogous to class-H amplifier operation. For example, for each operational state (the number of operational states corresponds to the number of segments of the input signal, as described with reference to FIG. 2), the power consumption can be reduced according to the signal level to supply power to the DEMs and DACs and other circuit elements that are enabled and used. Thus, when the signal is at small amplitude or when small amplitude signals are reproduced, the power consumption can be greatly reduced.

Referring now to FIGS. 3A and 3B, FIG. 3A is a data diagram illustrating segmenting of data for an 8-bit digital input signal in accordance with one embodiment. For purposes of illustration, a bit is considered to have either a zero or non-zero (e.g., one) value, but other forms of representation of digital data are not excluded and can also be used. FIG. 3A provides a schematic representation of data for the 8 bits of digital input signal 104, as shown in FIGS. 1 and 2, for example. The 8 bits of the digital input signal 104, referred to as I, can be numbered from 0 to 7 for identification of each bit, with bit 0 being indicated in the diagram. A canonical way of interpreting the value of data I is to assign each bit a value of 2 raised to the power of the bit's number. So bit 0 has a value of 1; bit 1 has a value of 2; bit 3 has a value of 4, and so on. Each bit represents a greater value, so bit 0 is referred to as least significant, and the highest number bit is referred to as most significant.

In the example provided by the embodiment illustrated in FIG. 1, the 8 bits of digital input signal 104, data I, is segmented into a 4-bit data segment A and 5-bit data segment X. Referring to FIG. 3B, data segment A can be provided by a first-order modulator M2, and 4-bit data segment A can be subtracted from 8-bit input signal I (with most significant bits aligned) at adder 320 to produce 5-bit digital signal X. Alignment of the most significant bits of I and A (as seen in FIG. 3A) requires A to multiplied by 16 so that X can be expressed as X=I−16A; therefore data segment A is given a weight of 16 and associated DAC 140a may be given the same weight and a gain of 16. The weight, 16, of data segment A may also be determined as the minimum amplitude of a signal (e.g., 1 at bit 4 and 0 at bits 5-7) requiring segment A for its expression. It may be seen from FIG. 3B, that signal X (when the amplitude of I is such that A is required for the expression of data segment I) may be the difference between the input and output of a noise shaper (first-order digital modulator M2), so it represents only the shaped quantization noise of the first-order digital modulator and does not contain any signal components. Thus, noise may be reduced and dynamic range increased.

Similarly, the 5-bit data segment X may be segmented into 3-bit data segment B and 3-bit data segment C. Referring again to FIG. 3B, 3-bit data segment B may be provided by a first-order modulator M3, and data segment B can be subtracted from 5-bit data segment X (with most significant bits aligned) at adder 330 to produce 3-bit digital signal C. Alignment of the most significant bits of X and B (as seen in FIG. 3A) requires B to multiplied by 4 so that C can be expressed as C=X−4B; therefore, data segment B is given a weight of 4 and associated DAC 140b is given the same weight and a gain of 4. The weight, 4, of data segment B may also be determined as the minimum amplitude of a signal (e.g., 1 at bit 2 and 0 at bits 3-4) requiring segment B for its expression.

Likewise, C may be given a weight of 1, and associated DAC 140c may be given the same weight and may be configured to have a gain of one. It may be seen from FIG. 3B, that signal C (when the amplitude of I is such that B is required for the expression of data segment I) may be the difference between the input and output of a noise shaper (first-order digital modulator M3), so it may represent only the shaped quantization noise of the first-order digital modulator M3 and not contain any signal components. It may also be seen from FIGS. 3A and 3B, that input signal 104, I, can be expressed as I=16A+4B+C. When the amplitude of signal I is such that I can be expressed as I=4B+C, or for low amplitude I, I=C, e.g., data segment A, or respectively A and B, are not required for expressing I, certain portions of data splitter 110, such as modulators or adders as illustrated by the example of FIG. 3B, may be disabled (e.g., their power supply switched off) or bypassed (e.g., signal not routed to them), for example, by envelope detector and configuration control 120.

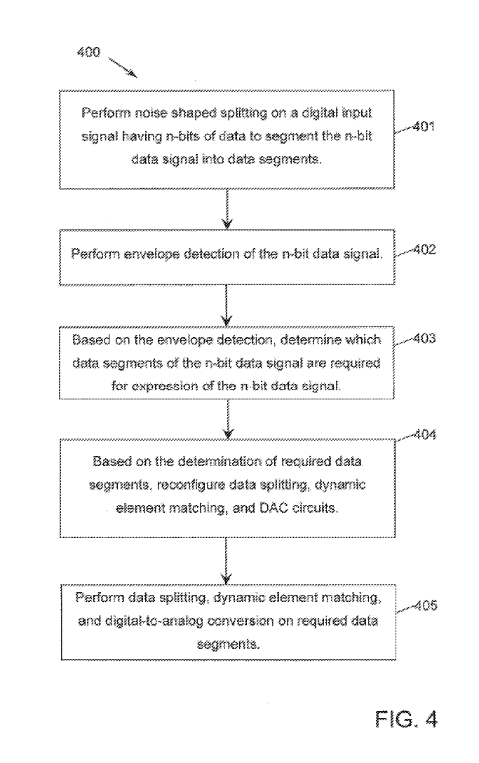

FIG. 4 is a flow chart of a method 400 of digital-to-analog conversion of a digital input signal, according to an embodiment. Method 400 may include various actions and operations of circuit elements and modules as described by the preceding examples.

Method 400 may include an action 401 of performing noise shaped splitting on a digital input signal having n-bits of data to segment the n-bit data signal into data segments. Such operations may be performed on 8-bit digital input signal 104, for example, by data splitter 110 illustrated in FIG. 1, FIG. 2, and FIG. 3B.

At action 402, envelope detection may be performed on the n-bit data signal, such as 8-bit digital input signal 104, as represented by data segment I, illustrated in FIG. 3A. Envelope detection may be performed, for example, by envelope detector and configuration control 120 illustrated in FIG. 1 determining the amplitude of the input signal. Amplitude may be determined by logic circuits of envelope detector and configuration control 120, for example, that read data segment I and determine what is the most significant bit of data segment I that is a non-zero bit.

Based on the envelope detection, envelope detector and configuration control 120, at action 403, may determine which data segments of the n-bit data signal are required for expression of the n-bit data signal. In general, and in particular as described with reference to FIG. 2, the required data segments will be the data segments of least weight, and corresponding to the weighted DACs of least weight, that can be used to express the data signal I, and the required data segments will exclude those data segments of greater weight that do not contain any non-zero data in data signal I.

At action 404, based on the determination of required data segments, envelope detector and configuration control 120 may switch on and off various switches or otherwise control the configuration of system 100 to reconfigure data splitting (e.g., data splitter 110), dynamic element matching (e.g., DEMs 130), and DAC circuits (e.g., DACs 140). The reconfiguration may reduce power consumption of system 100 while simultaneously or concurrently improving the dynamic range of system 100, as illustrated by the example described with reference to FIG. 2. Thus, at action 405, method 400 may result in performing data splitting, dynamic element matching, and digital-to-analog conversion on the required data segments, such as segment C; segments C and B; or segments C, B, and A, depending on the amplitude of signal I, as described with reference to FIGS. 3A and 3B.

Where applicable, various embodiments provided by the present disclosure may be implemented using hardware, software, or combinations of hardware and software. Also, where applicable, the various hardware components and/or software components set forth herein may be combined into composite components comprising software, hardware, and/or both without departing from the spirit of the present disclosure. Where applicable, the various hardware components and/or software components set forth herein may be separated into sub-components comprising software, hardware, or both without departing from the scope of the present disclosure. In addition, where applicable, it is contemplated that software components may be implemented as hardware components and vice-versa.

Software, in accordance with the present disclosure, such as program code and/or data, may be stored on one or more computer readable mediums. It is also contemplated that software identified herein may be implemented using one or more general purpose or specific purpose computers and/or computer systems, networked and/or otherwise. Where applicable, the ordering of various steps described herein may be changed, combined into composite steps, and/or separated into sub-steps to provide features described herein.

The foregoing disclosure is not intended to limit the present disclosure to the precise forms or particular fields of use disclosed. As such, it is contemplated that various alternate embodiments and/or modifications to the present disclosure, whether explicitly described or implied herein, are possible in light of the disclosure. Having thus described embodiments of the present disclosure, persons of ordinary skill in the art will recognize that changes may be made in form and detail without departing from the scope of the present disclosure. Thus, the present disclosure is limited only by the claims.

What is claimed is:

1. A digital-to-analog conversion system comprising:
a data splitter operable to split a digital input signal into a plurality of data segments, wherein the digital input signal is expressed as a combination of the plurality of data segments;
a plurality of signal paths, each of the plurality of signal paths having a plurality of processing elements operable to receive and process a corresponding one of the plurality of data segments; and
a configuration controller operable to determine a subset of the plurality of data segments sufficient to express the digital input signal and selectively provide power to the processing elements of each signal path for selectively processing each data segment in the subset of data segments.

2. The system of claim 1, wherein the subset of data segments comprises data segments required for a combination of the subset of data segments to express the digital input signal, and wherein the configuration controller is operable to feed the required data segments to corresponding processing elements.

3. The system of claim 1, further comprising an envelope detector operable to determine which of the plurality of data segments are sufficient to form a combination to express the digital input signal.

4. The system of claim 1, wherein each of the plurality of data segments has a weight corresponding to a level of amplitude of the digital input signal and the configuration control is operable to provide power to the processing elements corresponding to the data segments of a minimum weight up to and including the data segment having the weight corresponding to a current amplitude of the input signal.

5. The system of claim 1, further comprising:
a dynamic element matching module arranged to receive an output of the data splitter and a control signal from configuration controller, the dynamic element matching module operable to receive one of the data segments and perform data shuffling on the data segment when enabled by the configuration controller.

6. The system of claim 1, further comprising:
a digital-to-analog converter controlled by the configuration controller, the digital-to-analog converter operable to receive one of the data segments and produce an analog signal at a gain corresponding to a determined weight of the received one of the data segments.

7. The system of claim 1, wherein the data splitter further comprises a plurality of digital modulators controlled by the configuration controller, the plurality of digital modulators operable to generate data segments having weights corresponding to a level of amplitude of the digital input signal, the each data segment having a weight corresponding to a level of amplitude from a minimum amplitude up to and including a weight corresponding to a current amplitude of the input signal.

8. A digital-to-analog conversion system comprising:
a data splitter operable to split a digital input signal into a plurality of data segments, wherein the digital input signal is expressed as a combination of one or more of the plurality of data segments;
a plurality of signal paths, each signal path having a plurality of processing elements operable to receive and process a corresponding one of the plurality of data segments; and
a configuration controller operable to selectively supply power to processing elements used for processing the plurality of data segments, wherein the configuration controller disables processing elements not required for a subset of data segments to express the digital input signal.

9. The system of claim 8, wherein the configuration controller is operable to bypass processing elements corresponding to the plurality of data segments not required for the subset to express the digital input signal.

10. The system of claim 8, further comprising an envelope detector operable to determine which of the plurality of data segments are not required for the subset to express the digital input signal.

11. The system of claim 8, wherein each of the plurality of signal paths has an associated weight corresponding to a level of amplitude of the digital input signal and wherein the configuration controller is operable to selectively supply power to the processing elements used for processing the plurality of data segments corresponding to a minimum weight up to and including the data segment having the weight corresponding to a current amplitude of the input signal.

12. The system of claim 8, further comprising:
a dynamic element matching module connected to the data splitter and controlled by the configuration controller, the dynamic element matching module operable to receive a corresponding one of the data segments and perform data shuffling on the data segment when enabled by the configuration control.

13. The system of claim 8, wherein each signal path has an associated weight corresponding to a level of amplitude of the digital input signal, the system further comprising a digital-to-analog converter controlled by the configuration controller and operable to receive a corresponding one of the data segments and produce an analog signal at a gain corresponding to a weight of the data segment.

14. The system of claim 12, wherein each data segment has a weight corresponding to a level of amplitude of the digital input signal, the system further comprising a digital-to-analog converter controlled by the configuration controller and operable to receive a corresponding one of the shuffled data segments from the dynamic element matching module and produce an analog signal at a gain corresponding to a weight of the data segment.

15. A method of converting a digital input signal to an analog signal, the method comprising:
splitting the digital input signal into a plurality of data segments, wherein each data segment comprises a portion of the digital input signal such that the digital input signal is expressed by a weighted sum of the data segments, wherein at least one data segment having a minimum weight is required for the weighted sum to express the digital input signal; and
controlling a configuration of a signal processor to selectively enable and disable processing elements used for processing the data segments, wherein data segments that are required for the weighted sum to express the digital input signal are enabled, and data segments that are not required for the weighted sum to express the digital input signal are disabled.

16. The method of claim 15, further comprising:
controlling the configuration of the signal processor to feed the data segments required for the weighted sum to express the digital input signal to processing elements used for processing those data segments, and to bypass those processing elements corresponding to data segments that are not required for the weighted sum to express the digital input signal.

17. The method of claim 15, further comprising:
determining which of the plurality of data segments are required for the weighted sum to express the digital input signal.

18. The method of claim 15, further comprising:
assigning a weight to each data segment such that each weight corresponds to a range of amplitude values of the digital input signal; and
controlling the configuration of the signal processor to selectively provide power to the processing elements corresponding to the data segments of a minimum weight up to and including the data segment having the weight corresponding to a current amplitude of the input signal.

19. The method of claim 15, further comprising:
assigning a weight to each data segment such that each weight corresponds to a distinct level of amplitude of the digital input signal;
controlling the configuration of the signal processor to enable dynamic element matching on the data segments corresponding to the minimum weight and data segments having weights up to and including the weight of the data segment corresponding to a current amplitude of the input signal; and
performing dynamic element matching according to the current configuration.

20. The method of claim 15, further comprising:
assigning a weight to each data segment such that each weight corresponds to a distinct level of amplitude of the digital input signal;
controlling the configuration of the signal processor to selectively enable digital-to-analog converters on the signal path corresponding to the data segments having a minimum weight up to and including the data segments having the weight corresponding to a current amplitude of the input signal; and
converting, according to the current configuration, a data segment to an analog signal at a gain corresponding to the weight of the data segment.
